(19) United States
(12) Patent Application Publication
(10) Pub. No.: US 2010/0097772 A1
(43) Pub. Date: Apr. 22, 2010

(54) Circuit board connecting structure and display device comprising the same

(75) Inventors: Po-Shan Huang, Miao-Li (TW); Jia-Shyong Cheng, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 12/589,230

(22) Filed: Oct. 19, 2009

(30) Foreign Application Priority Data
Oct. 17, 2008 (CN) 200820212657.4

(51) Int. Cl. H05K 1/11

(52) U.S. Cl. 361/749; 361/803

(57) ABSTRACT

A display device includes a circuit board connecting structure. The circuit board connecting structure includes a first circuit board, a soldering layer, and a second circuit board. The first circuit board includes a baseboard and a plurality of parallel elongate first electrodes defined at a predetermined area. The second circuit board includes a plurality of parallel elongate second electrodes positioned at the predetermined area. The second electrodes are electrically connected to the corresponding first electrodes via the soldering layer. A space defined by the projection of the second electrodes to the baseboard of the first circuit board is filled in by the soldering layer.

### BACKGROUND

1. Technical Field

The present disclosure relates to circuit board connecting structures and display devices, and particularly to a circuit board connecting structure and a display device comprising the circuit board connecting structure.

2. Description of Related Art

In general, a display panel of a display device receives driving signals from a printed circuit board (PCB) to display a corresponding image. The display device is usually electrically connected to the PCB via a flexible printed circuit board (FPC). In one such example, a plurality of first golden fingers may be formed at a side of the PCB with a plurality of second golden fingers may be formed at a side of the FPC. The first golden fingers correspond to the second golden fingers and all have the same width. The plurality of first golden fingers are electrically connected to the corresponding second golden fingers via heat pressure soldering technique.

However, since the width of the first golden fingers are equal to the width of the second golden fingers, solder only can be received in a small space between the first golden fingers and the corresponding second golden fingers, after the heat pressure soldering technique. Therefore, pressure of heat pressure soldering technique should be accurate to avoid overflowing of the solder, which may cause short circuits. In addition, because the accuracy of the heat pressure soldering technique is limited, an arrangement density of the first golden fingers and the second golden fingers is sacrificed in order to ensure the display device qualifies, which is a disadvantage to miniaturization.

### BRIEF DESCRIPTION OF THE DRAWINGS

FIG. 1 is a sketch view of an exemplary embodiment of a display device including a first circuit board and a display panel.

FIG. 2 is a sketch view of one embodiment of the first circuit board of the display device of FIG. 1.

FIG. 3 is a cross-sectional view of one embodiment of the display device of FIG. 1, taken alone the line

FIG. 4 is a sketch view of one embodiment the display panel of the display device of FIG. 1.

### DETAILED DESCRIPTION

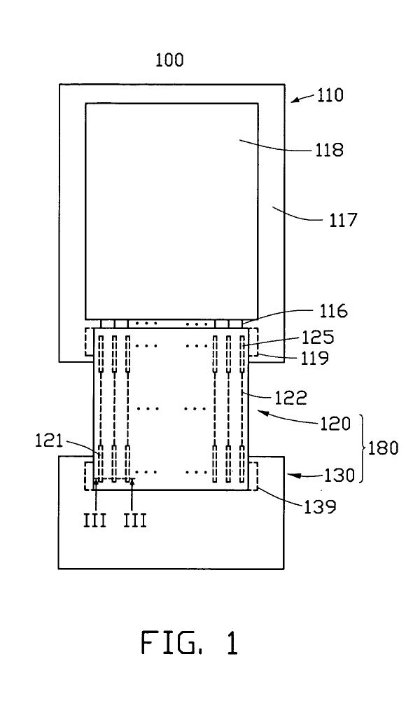

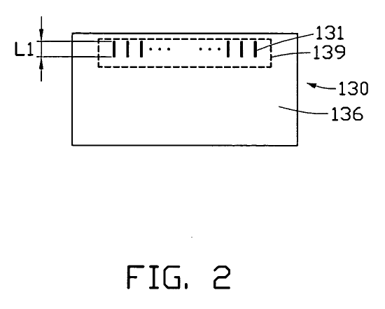

Referring to FIGS. 1-3, an exemplary embodiment of a display device 100 includes a display panel 110, a first circuit board 130, a second circuit board 120, and a soldering layer 141 including a plurality of soldering units 140. The first circuit board 130 and the second circuit board 120 are electrically interconnected to each other via the soldering layer 141. The first circuit board 130, the soldering layer 141, and the second circuit board 120 together form a circuit board connecting structure 180.

The first circuit board 130 may be a rigid printed circuit board, which includes an insulating baseboard 136 and a plurality of first electrodes 131 protruding from the baseboard 136. The first electrodes 131 are defined at a determined area 139 of the first circuit board 130. In one exemplary embodiment, the determined area 139 is defined at a rim of the first circuit board 130. In other exemplary embodiments, the determined area 139 can be defined at another place of the first circuit board 130, such as a center of the first circuit board 130.

The plurality of first electrodes 131 are elongate electrodes arranged in parallel, which are generally named as golden fingers. A distance D0 between each two adjacent first electrodes 131 may range from about 120 microns (μm) to about 500 μm, in one example. In one exemplary embodiment, the distance D0 is about 300 μm. A proportion of the distance D0 to a first width W1 of each of the plurality of first electrodes 131 ranges from about 2.5 to about 7.5. A length L1 of each of the plurality of first electrodes 131 may be about 2700 μm, in one example.

The interconnected part of the second circuit board 120 and the first circuit board 130 corresponds to the determined area 139 of the first circuit board 130. The second circuit board 120 may be a flexible printed circuit board, which includes a plurality of electrically conductive paths 122. Each of the conductive paths 122 includes a first end and a second end. A plurality of elongated second electrodes 121 in parallel are defined at the corresponding first ends of the conductive paths 122. A plurality of elongated third electrodes 125 are defined at the corresponding second ends of the conductive paths 122.

In one exemplary embodiment, the first ends and the second ends of the plurality of conductive paths 122 are defined at two opposite rims of the second circuit board 120. The plurality of second electrodes 121 correspond to the plurality of first electrodes 131, and are also generally named as golden fingers. A second width W2 of each of the plurality of second electrodes 121 is greater than the first width W1 of each of the plurality of first electrodes 131. In one exemplary embodiment, a proportion of the second width W2 to the first width W1 ranges from about 1.5 to about 5.

The plurality of soldering units 140 are defined between the plurality of first electrodes 131 and the corresponding second electrodes 121, and cover surfaces of the plurality of first electrodes 131 widthwise. The soldering units 140 may be as long as or shorter than the corresponding first electrodes 131. The soldering units 140 are sufficiently or approximately filled into a space defined by a projection of the corresponding second electrodes 121 onto the baseboard 136 of the first circuit board 130, which means that the soldering units 140 may be filled into the whole or most of the projection spaces.

A proportion of a height D1 of each first electrode 131 protruding from the baseboard 136 to a distance D2 between the baseboard 136 and each second electrode 121 ranges from about 0.6 to about 1. In one exemplary embodiment, the proportion of the height D1 to the distance D2 ranges from about 0.8 to about 0.9. A distance between the first electrode 131 and a corresponding second electrode 121 ranges from about 2 μm to 20 μm, in one example. A sectional area of each soldering unit 140 is greater than a sectional area of a corresponding first electrode 131.

In analysis, if the first width W1 of the first electrode 131 is equal to the second width W2 of the second electrode 121, which is well known in a common circuit board connecting structure, a substantial size of the soldering unit 140 can be obtained according to W2×(D2−D1)×L1. However, since the first width W1 of the first electrode 131 is less than the second width W2 of the second electrode 121 in the present circuit board connecting structure 180, an additional space is provided at two opposite sides of each first electrode 131 to receive the corresponding soldering unit 140. A capacity of the additional space can be approximately obtained according to (W2−W1)×D1×L1.

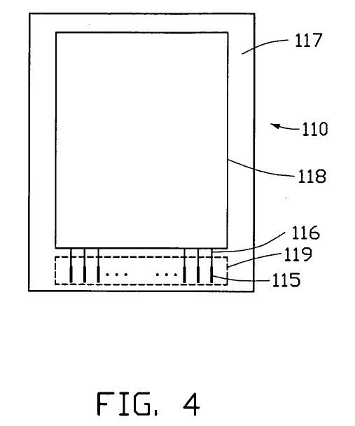

Referring to FIG. 4, the display panel 110 is a liquid crystal panel, which includes a display area 118 and a peripheral area 117 surrounding the display area 118. A connection area 119 is defined on the peripheral area 117, and is connected to the display area 118 via a plurality of signal transmission lines 116, thereby to transmit driving signals from the second circuit board 120 to drive the display area 118 to display a corresponding image.

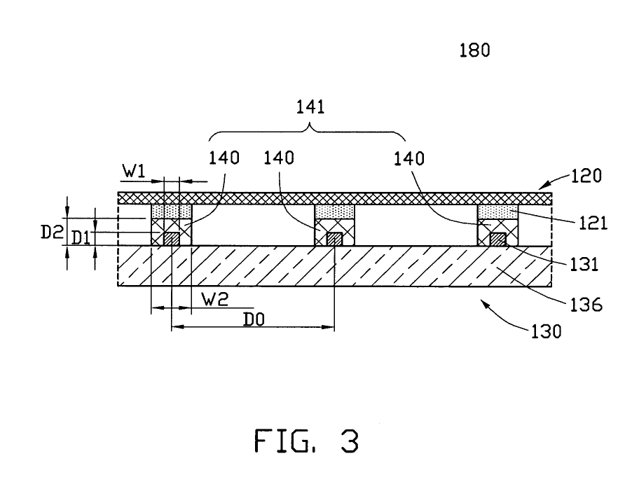

In one exemplary embodiment, the connection area 119 includes a plurality of elongated extending electrodes 115. Each of the elongated extending electrodes 115 is connected to a corresponding third electrode 125 of the second circuit board 120 via soldering. Connections between the extending electrodes 115 and the third electrodes 125 can be made the same as the connections between the first electrodes 131 and the second electrodes 121 as shown in FIG. 3, which means that a width of each of the extending electrodes 115 is less than a width of each of the third electrodes 125. Therefore, solder between the extending electrode 115 and the third electrode 125 can be sufficiently and approximately filled into a spaces defined by projection of the third electrodes 125 onto the connection area 119 of the display panel 110. In another exemplary embodiment, the connection area 119 may be electrically connected to the second circuit board 120 via a connector or anisotropic conductive paste.

In the present exemplary embodiment of the display device 100, the width of the first electrode 131 is less than that the width of the second electrode 121 in the circuit board connecting structure 180, therefore, the soldering unit 140 can be received in the additional space provided at opposite sides of the corresponding first electrode 131 in the space defined by the projection of the second electrodes 121 onto the baseboard 136 of the first circuit board 130. The additional space can reduce possibility of solder overflowing, thereby avoiding creation of short circuits, and increase an arrangement density of the first electrode 131 and the second electrode 121. Therefore, the quality of the display device 100 is improved and the size of the display device 100 is reduced

Furthermore, since the first electrode 131 is electrically connected to the second electrode 121 via soldering rather than expensive anisotropic conductive film (ACF), the cost of the display device 100 is reduced, and the circuit board connecting structure 180 is much stronger, thereby the first electrode 131 and the second electrode 121 are not easily disconnected through mishap.

In another exemplary embodiment, the first circuit board 130 is a flexible printed circuit board, and the second circuit board 120 is a rigid printed circuit board, and the first width W1 of the first electrode 131 is greater than the second width W2 of the second electrode 121.

It is to be understood, however, that even though numerous characteristics and advantages of the present disclosure have been set forth in the foregoing description, together with details of the structure and function of the disclosure, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. A circuit board connecting structure, comprising:
a first circuit board comprising a baseboard and a determined area defined on the first circuit board; wherein the determined area comprises a plurality of first electrodes arranged in parallel;
a soldering layer; and
a second circuit board forming a plurality of second electrodes arranged in parallel, corresponding to the plurality of first elongate electrodes of the first circuit board;
wherein a width of each of the second electrodes is greater than a width of a corresponding first electrode, and wherein a space defined by a projection of the corresponding second electrode onto the baseboard of the first circuit board is filled in by the soldering layer.

2. The circuit board connecting structure of claim 1, wherein a distance between two adjacent first electrodes ranges from about 120 microns (μm) to about 500 μm.

3. The circuit board connecting structure of claim 1, wherein the plurality of first electrodes protrude from the baseboard of the first circuit board, and the soldering layer covers the plurality of first electrodes.

4. The circuit board connecting structure of claim 3, wherein a proportion of a height of each first electrode protruding from the baseboard to a distance between the baseboard and the second electrode ranges from about 0.6 to about 1.

5. The circuit board connecting structure of claim 1, wherein a proportion of a distance between two adjacent first electrodes to a height of each first electrode ranges from about 2.5 to about 7.5.

6. The circuit board connecting structure of claim 1, wherein a proportion of a width of the second electrode to a width of each first electrode ranges from about 1.5 to about 5.

7. The circuit board connecting structure of claim 1, wherein at least one of the first circuit board and the second circuit board is a flexible printed circuit board.

8. A display device, comprising:
a display panel comprising a plurality signal transmission lines;
a first circuit board comprising a baseboard and a plurality of first electrodes arranged on the baseboard in parallel; and
a second circuit board comprising a plurality of electric conductive paths to electrically connect the signal transmission lines of the display panel to the corresponding first electrodes;
wherein a plurality of second electrodes in parallel are formed on ends of the corresponding electric conductive paths, and the plurality of second electrodes are electrically connected to the corresponding first electrodes via a soldering layer; wherein a width of each of the second electrodes is greater than a width of each of the first electrodes, and a space defined by a projection of the second electrode onto the baseboard of the first circuit board is filled in by the soldering layer.

9. The display device of claim 8, wherein a distance between two adjacent first electrodes ranges from about 120 microns (μm) to about 500 μm.

10. The display device of claim 8, wherein a proportion of a distance between two adjacent first electrodes to a height of each first electrode ranges from about 2.5 to about 7.5.

11. The display device of claim 8, wherein a proportion of a width of each second electrode to a width of each first electrode ranges from about 1.5 to about 5.

12. The display device of claim 8, wherein at least one of the first circuit board and the second circuit board is a flexible printed circuit board.

13. A display device, comprising:
a display panel comprising a plurality signal transmission lines;
a rigid printed circuit board comprising a baseboard and a plurality of first electrodes arranged in parallel protruding from the baseboard;
a flexible printed circuit board comprising a plurality of electric conductive paths to electrically connect the signal transmission lines of the display panel to the corresponding first electrodes;
wherein a plurality of second electrodes in parallel are formed on ends of the corresponding electric conductive paths, and the plurality of second electrodes are electrically connected to the corresponding first electrodes via a plurality of soldering units, respectively; wherein a space defined by a projection of a corresponding second electrode onto the baseboard is filled by each of the plurality of soldering units, and a sectional area of each soldering unit is greater than a sectional area of each first electrode; wherein a proportion of a height of the first electrode protruding from the baseboard to a distance between the baseboard and the plurality of second electrodes ranges from about 0.6 to about 1.

14. The display device of claim 13, wherein a distance between two adjacent first electrodes ranges from about 120 microns (μm) to about 500 μm.

15. The display device of claim 13, wherein a proportion of a distance between two adjacent first electrodes to a height of each first electrode ranges from about 2.5 to about 7.5.

16. The display device of claim 13, wherein a proportion of a width of each second electrode to a width of each first electrode ranges from about 1.5 to about 5.
